(19) United States
(12) Patent Application Publication
(10) Pub. No.: US 2025/0216730 A1
(43) Pub. Date: Jul. 3, 2025

(54) ELECTRO-OPTICAL DEVICE AND ELECTRONIC APPARATUS

(71) Applicant: SEIKO EPSON CORPORATION, Tokyo (JP)

(72) Inventor: Yuki YASHIRO, Chitose-shi (JP)

(73) Assignee: SEIKO EPSON CORPORATION, Tokyo (JP)

(21) Appl. No.: 19/001,640

(22) Filed: Dec. 26, 2024

(30) Foreign Application Priority Data
Dec. 27, 2023 (JP) 2023-221154

(51) Int. Cl. G02F 1/1362; G02F 1/1368; H10D 86/40

(52) U.S. Cl. CPC G02F 1/136209; G02F 1/136286; G02F 1/1368; H10D 86/451

(57) ABSTRACT

An electro-optical device includes a substrate, a transistor including a semiconductor layer, a gate insulating film, and a gate electrode that are aligned in a direction away from the substrate, a first insulating layer covering the transistor, a first contact provided at the first insulating layer and coupled to the gate electrode, a first light shielding film provided at the first insulating layer, and a second light shielding film provided between the substrate and the semiconductor layer, in which the second light shielding film overlaps the semiconductor layer when viewed in a normal direction of the substrate and is provided at a different position from the gate electrode.

The present application is based on, and claims priority from JP Application Serial Number 2023-221154, filed Dec. 27, 2023, the disclosure of which is hereby incorporated by reference herein in its entirety.

### BACKGROUND

### 1. Technical Field

The present disclosure relates to an electro-optical device and an electronic apparatus.

### 2. Related Art

For electronic apparatuses such as projectors, for example, electro-optical devices such as liquid crystal display devices whose optical characteristics can be changed for each pixel are used. An electro-optical device disclosed in JP-A-2020-160208 is known as an example of the electro-optical devices.

The electro-optical device described in JP-A-2020-160208 includes a transistor that includes a semiconductor layer, a gate electrode, and a gate insulating film provided therebetween. The gate electrode of the transistor is electrically coupled to a first contact hole provided at an interlayer insulating film above the gate electrode. Further, a light shielding layer is provided below the transistor. The light shielding layer overlaps the gate electrode and the gate insulating film in plan view.

However, when the light shielding layer overlaps the gate insulating film in plan view, and when a hole for forming the first contact hole is formed in the interlayer insulating layer by etching, there is a concern that the gate insulating film may be destroyed by the etching.

### SUMMARY

According to an aspect of the present disclosure, an electro-optical device includes a substrate, a transistor including a semiconductor layer, a gate insulating film, and a gate electrode that are aligned in a direction away from the substrate, a first insulating layer covering the transistor, a first contact provided at the first insulating layer and coupled to the gate electrode, a first light shielding film provided at the first insulating layer, and a second light shielding film provided between the substrate and the semiconductor layer, in which the second light shielding film overlaps the semiconductor layer when viewed in a normal direction of the substrate and is provided at a different position from the gate electrode.

According to an aspect of the present disclosure, an electronic apparatus includes an electro-optical device, and a control unit configured to control an operation of the electro-optical device.

### BRIEF DESCRIPTION OF THE DRAWINGS

FIG. 1 is a plan view of an electro-optical device according to an embodiment.

FIG. 2 is a cross-sectional view taken along line A-A of the electro-optical device shown in FIG. 1.

FIG. 3 is a diagram schematically showing a peripheral circuit in the electro-optical device of FIG. 1.

FIG. 4 is an equivalent circuit diagram showing an electrical configuration of an element substrate of FIG. 1.

FIG. 5 shows a portion of the element substrate in a display region in FIG. 2.

FIG. 6 is a cross-sectional view taken along line A1-A1 in FIG. 4.

FIG. 7 is a cross-sectional view taken along line A2-A2 in FIG. 4.

FIG. 8 shows a portion of a scanning line drive circuit in a peripheral region of FIG. 3.

FIG. 9 is a diagram showing a planar arrangement of transistors included in a unit circuit of FIG. 8.

FIG. 10 is a diagram showing a planar arrangement of a second light shielding film and a semiconductor layer in FIG. 8.

FIG. 11 is a diagram showing a planar arrangement of a first light shielding film and a second light shielding film in FIG. 8.

FIG. 12 is a diagram for describing etching of contact holes in a comparative example.

FIG. 13 is a diagram for describing etching of contact holes in this embodiment.

FIG. 14 is a diagram showing a planar arrangement of a fourth light shielding film and a second transistor shown in FIG. 6.

FIG. 15 is a cross-sectional view showing a first light shielding film and a second light shielding film in a second embodiment.

FIG. 16 is a plan view showing the first light shielding film and the second light shielding film in the second embodiment.

FIG. 17 is a cross-sectional view showing a first light shielding film and a second light shielding film in a third embodiment.

FIG. 18 is a plan view showing the first light shielding film and the second light shielding film in the third embodiment.

FIG. 19 is a cross-sectional view showing a first light shielding film in a first modification example.

FIG. 20 is a diagram showing a portion of a display region of an element substrate in a second modification example.

FIG. 21 is a diagram showing a portion of a peripheral region of the element substrate in the second modification example.

FIG. 22 is a perspective view showing a personal computer as an example of an electronic apparatus.

FIG. 23 is a plan view showing a smartphone as an example of an electronic apparatus.

FIG. 24 is a schematic diagram showing a projector as an example of an electronic apparatus.

FIG. 25 is a diagram showing a planar arrangement of a fourth light shielding film and a second transistor in a modification example.

### DESCRIPTION OF EMBODIMENTS

Hereinafter, preferred embodiments of the present disclosure will be described with reference to the accompanying drawings. In the drawings, dimensions or scales of respective parts may be appropriately different from actual ones, and there are portions schematically shown to facilitate understanding. Further, the scope of the present disclosure is not limited to these forms unless there is a particular statement that limits the present disclosure in the following description.

### A. Electro-Optical Device

### 1. Basic Configuration

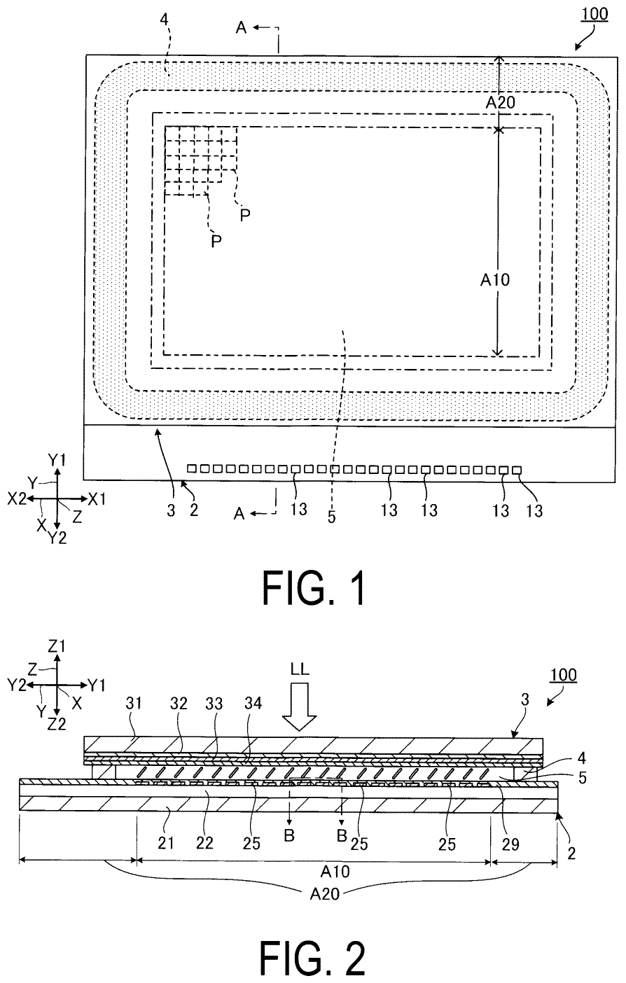

FIG. 1 is a plan view of an electro-optical device 100 according to an embodiment. FIG. 2 is a cross-sectional view taken along line A-A of the electro-optical device 100 shown in FIG. 1. In the following description, an X-axis, a Y-axis, and a Z-axis which are orthogonal to each other will be used appropriately for convenience of description. Further, one direction along the X-axis is referred to as an X1 direction, and a direction opposite to the X1 direction is referred to as an X2 direction. Similarly, one direction along the Y-axis is referred to as a Y1 direction, and a direction opposite to the Y1 direction is referred to as a Y2 direction. One direction along the Z-axis is referred to as a Z1 direction, and a direction opposite to the Z1 direction is referred to as a Z2 direction.

Further, in this specification, “an element β on an element α” means that the element β is located on the side above the element α. Thus, “an element β on an element α” includes not only a case where the element β is in direct contact with element α, but also a case where the element α and the element β are separated from each other. Further, “electrical coupling” between an element o and an element β includes not only a configuration where the element α and the element β are electrically coupled by being directly bonded to each other, but also a configuration where the element o and the element β are electrically coupled indirectly through another conductive material.

The electro-optical device 100 shown in FIGS. 1 and 2 is a transmissive electro-optical device using an active matrix drive scheme. The electro-optical device 100 includes an element substrate 2, an opposing substrate 3, a frame-shaped sealing member 4, and a liquid crystal layer 5. As shown in FIG. 2, the element substrate 2, the liquid crystal layer 5 and the opposing substrate 3 are arranged in this order in the Z1 direction. Viewing from the Z1 direction or Z2 direction, which is a direction in which these overlap, is referred to as “plan view”. Further, although the shape of the electro-optical device 100 shown in FIG. 1 is a rectangular shape in plan view, the shape may have a polygonal shape or a circular shape other than a rectangular shape.

The element substrate 2 shown in FIG. 2 includes a first substrate 21 having light transmittance, a laminated body 22 having light transmittance, a plurality of pixel electrodes 25 having light transmittance, and a first orientation film 29 having light transmittance. The first substrate 21, the laminated body 22, the plurality of pixel electrodes 25, and the first orientation film 29 are laminated in this order in the Z1 direction. In addition, “light transmittance” means transmittance of visible light and preferably indicates that the transmittance to visible light is 50% or more.

The first substrate 21 is equivalent to a “substrate”. The first substrate 21 is a flat plate having light transmittance and an insulating property, and is constituted by a glass substrate or a quartz substrate, for example. Further, a normal direction of the first substrate 21 matches a direction along the Z-axis. The laminated body 22 includes a plurality of insulating films having light transmittance. In addition, the laminated body 22 is provided with various wiring lines and the like. The pixel electrode 25 is used for applying an electric field to the liquid crystal layer 5. The pixel electrode 25 includes a transparent conductive material such as indium tin oxide (ITO), indium zinc oxide (IZO), and fluorine-doped tin oxide (FTO). Although not shown in the drawings, the element substrate 2 includes a plurality of dummy pixel electrodes surrounding the plurality of pixel electrodes 25 in plan view. In addition, the first orientation film 29 has light transmittance and an insulating property. The first orientation film 29 aligns liquid crystal molecules in the liquid crystal layer 5. The first orientation film 29 is disposed to cover the plurality of pixel electrodes 25. The material of the first orientation film 29 is polyimide, silicon oxide, and the like.

The opposing substrate 3 is disposed to face the element substrate 2. The opposing substrate 3 includes a second substrate 31 having light transmittance, an inorganic insulating layer 32 having light transmittance, a common electrode 33 having light transmittance, and a second orientation film 34 having light transmittance. In addition, although not shown in the drawings, the opposing substrate 3 includes a light shielding parting that surrounds the plurality of pixel electrodes 25 in plan view. “Light shielding property” means a light shielding property against visible light, and preferably means that the transmittance of the visible light is less than 50%, and more preferably 10% or less.

The second substrate 31, the inorganic insulating layer 32, the common electrode 33, and the second orientation film 34 are laminated in this order in the Z2 direction. The second substrate 31 is a flat plate having light transmittance and an insulating property, and is constituted by a glass substrate or a quartz substrate, for example. The inorganic insulating layer 32 has light transmittance and an insulation property, and is made of an inorganic material containing silicon, such as silicon oxide. The common electrode 33 is an opposing electrode disposed to face the plurality of pixel electrodes 25 through the liquid crystal layer 5. The common electrode 33 is used for applying an electric field to the liquid crystal layer 5. The common electrode 33 has light transmittance and conductivity. The common electrode 33 contains, for example, a transparent conductive material such as ITO, IZO, and FTO. The second orientation film 34 has light transmittance and an insulating property. The second orientation film 34 aligns liquid crystal molecules in the liquid crystal layer 5. The material of the second orientation film 34 is polyimide, silicon oxide and the like, for example.

The sealing member 4 is disposed between the element substrate 2 and the opposing substrate 3. The sealing member 4 is formed using, for example, an adhesive containing various curable resins such as an epoxy resin. The sealing member 4 may include a gap material made of an inorganic material such as glass.

The liquid crystal layer 5 is disposed at a region surrounded by the element substrate 2, the opposing substrate 3, and the sealing member 4. The liquid crystal layer 5 is an electro-optical layer whose optical characteristics change depending on an electric field. The liquid crystal layer 5 includes liquid crystal molecules having positive or negative dielectric anisotropy. An orientation of the liquid crystal molecules changes depending on a voltage applied to the liquid crystal layer 5.

The electro-optical device 100 includes a display region A10 in which an image is displayed, and a peripheral region A20 located outside the display region A10 in plan view. A plurality of pixels P disposed in a matrix are provided at the display region A10. The plurality of pixel electrodes 25 are disposed in a one-to-one relationship with the plurality of pixels P. The common electrode 33 described above is provided in common for the plurality of pixels P. Further, the peripheral region A20 surrounds the display region A10 in plan view.

In the present embodiment, the electro-optical device 100 is of a transmissive type. More specifically, as shown in FIG. 2, after light LL is incident on the opposing substrate 3, the light LL is modulated before being emitted from the element substrate 2, whereby an image is displayed. Light having been incident on the element substrate 2 may be modulated before being emitted from the opposing substrate 3, whereby an image is displayed.

Further, the electro-optical device 100 is applied to, for example, a display device that performs color display, of a personal computer, a smartphone, or the like, which will be described below. When the electro-optical device 100 is applied to the display device, a color filter is appropriately used for the electro-optical device 100. Further, the electro-optical device 100 is applied to, for example, a projection type projector, which will be described later. In this case, the electro-optical device 100 functions as a light valve. In this case, the color filter is omitted from the electro-optical device 100.

### 2. Peripheral Circuit

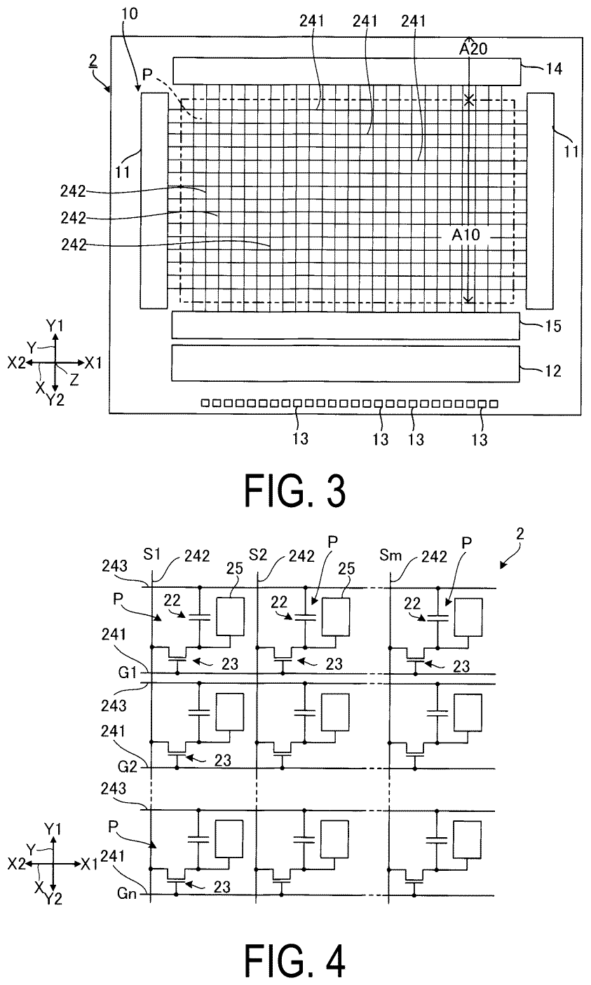

FIG. 3 is a diagram schematically showing the peripheral circuit 10 in the electro-optical device 100 of FIG. 1. As shown in FIG. 3, the peripheral region A20 of the electro-optical device 100 is provided with the peripheral circuit 10 and a plurality of external terminals 13. The plurality of external terminals 13 are coupled to wiring lines (not shown) which are routed from the peripheral circuit 10.

In the display region A10, n scanning lines 241 and m data lines 242 are disposed. n and m are integers equal to or greater than 2. The n scanning lines 241 extend in a direction along the X-axis and are aligned at equal intervals in a direction along the Y-axis. The m data lines 242 extend in a direction along the Y-axis and are aligned at equal intervals in a direction along the X-axis. The n scanning lines 241 and the m data lines 242 are electrically insulated from each other and are disposed in a grid pattern in plan view. A region surrounded by two adjacent scanning lines 241 and two adjacent data lines 242 corresponds to the pixel P.

In addition, the peripheral circuit 10 includes two scanning line drive circuits 11, a data line drive circuit 12, an inspection circuit 14, and a sampling circuit 15.

In the example shown in the drawing, the two scanning line drive circuits 11 are disposed to sandwich a display region A10. The scanning line drive circuit 11 includes a plurality of transistors. For example, odd-numbered scanning lines 241 are driven by the scanning line drive circuit 11 disposed on the left side of the display region A10, and even-numbered scanning lines 241 are driven by the scanning line drive circuit 11 disposed on the right side of the display region A10. The same scanning line 241 may be driven by the scanning line drive circuits 11 disposed on both the right and left sides, respectively.

The inspection circuit 14 is disposed, for example, on a side opposite to the plurality of external terminals 13 in the display region A10. The data lines 242 are coupled to the inspection circuit 14. The inspection circuit 14 is used to inspect an operational defect of the electro-optical device 100 by detecting an image signal during manufacture or shipment of the electro-optical device 100. The inspection circuit 14 includes, for example, a transistor provided for each data line 242. One source-drain region of the transistor is electrically coupled to the data line 242, and the other source-drain region is coupled to an inspection line (not shown). Furthermore, the gate of each transistor is electrically coupled to a control signal line (not shown).

The data line drive circuit 12 and the sampling circuit 15 are disposed, for example, on a side opposite to the inspection circuit 14 in the display region A10. The data line drive circuit 12 is electrically coupled to the m data lines 242 via the sampling circuit 15. Based on a sampling signal output from the data line drive circuit 12, the sampling circuit 15 samples an image signal and supplies it to the data lines 242.

The sampling circuit 15 includes a transistor provided for each data line 242. One source-drain region of the transistor is electrically coupled to the data line 242, and the other source-drain region is coupled to a constant potential line (not shown). In addition, the gate of each transistor is electrically coupled to a signal line (not shown) through which a sampling signal is supplied.

### 3. Electrical Configuration of Element Substrate 2

FIG. 4 is an equivalent circuit diagram showing an electrical configuration of the element substrate 2 of FIG. 1. As shown in FIG. 4, a second transistor 23, a pixel electrode 25, and a capacitive element 24 are provided for each pixel P in the display region A10 of the element substrate 2. The second transistor 23 is, for example, a thin film transistor (TFT) that functions as a switching element. Each second transistor 23 includes a gate, a source, and a drain. The pixel electrode 25 is electrically coupled to the drain of the corresponding second transistor 23. Furthermore, in the display region A10, n constant potential lines 243 are disposed in addition to the n scanning lines 241 and the m data lines 242 as described above.

Each of the n scanning lines 241 is electrically coupled to the gates of a plurality of corresponding second transistors 23. Scanning signals G1, G2, . . . , and Gn are supplied line-sequentially to the first to n-th scanning lines 241 from the scanning line drive circuit 11 described above.

The m data lines 242 are electrically coupled to the sources of the plurality of corresponding second transistors 23, respectively. Image signals S1, S2, . . . , and Sm are supplied in parallel to the first to m-th data lines 242 from the data line drive circuit 12 described above via the sampling circuit 15.

The n constant potential lines 243 extend in the X1 direction and are aligned at equal intervals in the Y2 direction. The n constant potential lines 243 are also electrically insulated from the n scanning lines 241 and the m data lines 242 and are disposed at intervals with respect to them. A constant potential Vcom is applied to each constant potential line 243. Each of the n constant potential lines 243 is electrically coupled to one of the two electrodes of the corresponding capacitive element 24. In addition, the other of the two electrodes of each capacitive element 24 is electrically coupled to the corresponding pixel electrode 25. Each capacitive element 24 is a storage capacitor for holding the potential of the pixel electrode 25. The constant potential Vcom is applied to one electrode of the capacitive element 24, and the other electrode is electrically coupled to the drain of the second transistor 23.

When the scanning signals G1, G2, . . . , and Gn become active sequentially and the n scanning lines 241 are selected sequentially, the second transistor 23 coupled to the selected scanning line 241 is set to be in an on state. Then, image signals S1, S2, . . . , and Sm having a magnitude according to a gradation to be displayed are taken into the pixel P corresponding to the selected scanning line 241 via the m data lines 242 and applied to the pixel electrode 25. Thereby, a voltage corresponding to the gradation to be displayed is applied to a liquid crystal capacitor formed between the pixel electrode 25 and the common electrode 33 in FIG. 2, and the orientation of the liquid crystal molecules changes in accordance with the applied voltage. In addition, the applied voltage is held by the capacitive element 24. Light is modulated due to such changes in the orientation of liquid crystal molecules, making gradation display possible.

### 4. Display Region A10

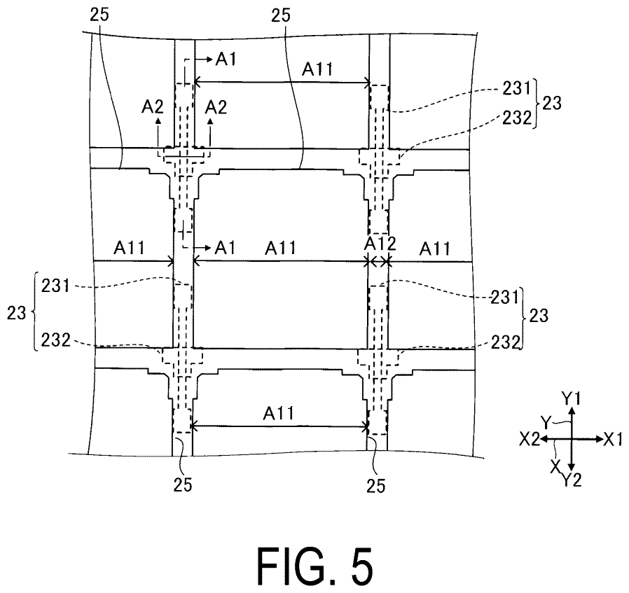

FIG. 5 shows a portion of the element substrate 2 in the display region A10 of FIG. 2. As shown in FIG. 5, the display region A10 includes a plurality of opening regions A11 and a light shielding region A12. The plurality of opening regions A11 are disposed in a matrix in plan view. The shape of the light shielding region A12 in plan view is a frame shape located between the plurality of opening regions A11. Each opening region A11 is a region in which the pixel electrode 25 is disposed, and is a region through which light passes. On the other hand, the light shielding region A12 is a region in which the second transistor 23 is disposed and which has a light shielding property. Although not shown in FIG. 5, various wiring lines such as the scanning lines 241, the data lines 242, and the constant potential lines 243 shown in FIG. 4, and the capacitive element 24 are disposed at the light shielding region A12.

### 5. Configuration of Light Shielding Region A12 of Element Substrate 2

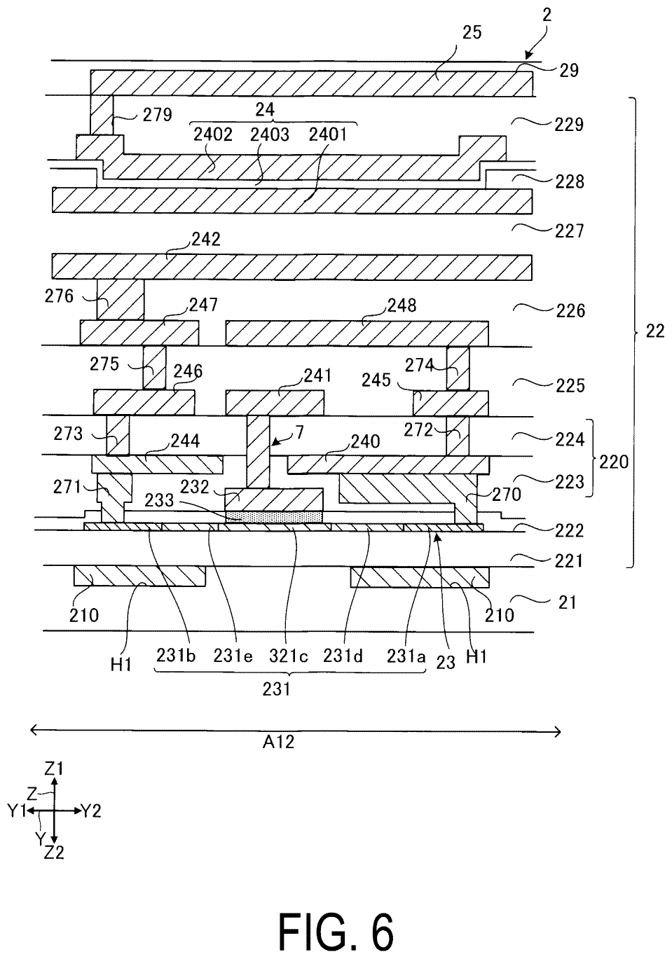

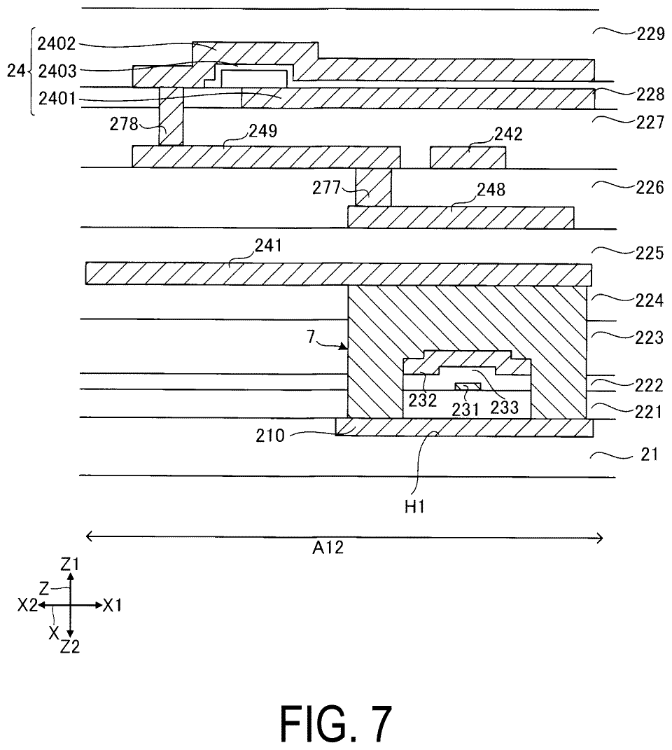

FIG. 6 is a cross-sectional view taken along line A1-A1 in FIG. 2. FIG. 7 is a cross-sectional view taken along line A2-A2 in FIG. 5.

As shown in FIGS. 6 and 7, the element substrate 2 includes the first substrate 21, which is a “substrate”, and the laminated body 22. The laminated body 22 includes a plurality of insulating layers 221, 222, 223, 224, 225, 226, 227, 228 and 229. The insulating layers 221, 222, 223, 224, 225, 226, 227, 228 and 229 are laminated in this order from the first substrate 21. Furthermore, the insulating layers 223 and 224 constitute the first insulating layer 220. The insulating layers 221 to 229 have light transmittance and an insulating property. The material of each of the insulating layers 221 to 229 is an inorganic material containing silicon, such as silicon oxide and silicon oxynitride.

The above-described second transistor 23, capacitive element 24, scanning line 241, and data line 242 are disposed at the light shielding region A12 of the laminated body 22. Furthermore, third light shielding films 244 and 240 are provided at the laminated body 22. In addition, relay electrodes 245, 246, 247, 248, and 249 are disposed at the laminated body 22. In addition, a plurality of fourth light shielding films 210 are disposed on the first substrate 21.

As described above, the first substrate 21 is constituted by, for example, a glass substrate or a quartz substrate. The first substrate 21 has a plurality of concave portions H1.

The fourth light shielding film 210 is disposed within the concave portion H1. The fourth light shielding film 210 is formed using, for example, a damascene method. The fourth light shielding film 210 is provided to curb incidence of light on the second semiconductor layer 231 of the second transistor 23. The first substrate 21 may not have the concave portion H1. In this case, the fourth light shielding film 210 is disposed on a flat surface of the first substrate 21 which faces in the Z1 direction.

The second transistor 23 is disposed on the insulating layer 221. The second transistor 23 includes the second semiconductor layer 231, the second gate insulating film 233, and the second gate electrode 232 which are aligned in a direction away from the first substrate 21. The second semiconductor layer 231 is disposed on the insulating layer 221. The second gate electrode 232 is disposed on the insulating layer 222. The second gate insulating film 233 is interposed between the second gate electrode 232 and the second semiconductor layer 231. A region of the insulating layer 222 which corresponds to the second gate electrode 232 in plan view is equivalent to the second gate insulating film 233.

The second transistor 23 has, for example, an lightly doped drain (LDD) structure. The second semiconductor layer 231 extends in a direction along the Y-axis. The second semiconductor layer 231 has a drain region 231a, a source region 231b, a channel region 231c, a lightly doped drain region 231d, and a lightly doped source region 231e. The channel region 231c is located between the drain region 231a and the source region 231b. The lightly doped drain region 231d is located between the channel region 231c and the drain region 231a. The lightly doped source region 231e is located between the channel region 231c and the source region 231b. The second semiconductor layer 231 is made of, for example, polysilicon. A region other than the channel region 231c is doped with impurities that increase conductivity. The impurity concentration in the lightly doped drain region 231d is lower than the impurity concentration in the drain region 231a. The impurity concentration in the lightly doped source region 231e is lower than the impurity concentration in the source region 231b. For example, the second transistor 23 may not have an LDD structure, and for example, the lightly doped source region 231e may be omitted.

The second gate electrode 232 is formed, for example, by doping polysilicon with impurities that increase conductivity. The second gate electrode 232 may be formed using a material having conductivity such as a metal, a metal oxide, or a metal compound. The second gate electrode 232 overlaps the channel region 231c of the second semiconductor layer 231 in plan view. In addition, the second gate insulating film 233 is constituted by a silicon oxide film formed, for example, by thermal oxidation or a chemical vapor deposition (CVD) method. A portion of the second transistor 23 overlaps the fourth light shielding film 210 in plan view.

As shown in FIG. 6, the third light shielding films 244 and 240 are disposed on the insulating layer 223. The third light shielding film 240 covers the lightly doped drain region 231d of the second semiconductor layer 231 in plan view. The third light shielding film 240 is coupled to the drain region 231a of the second semiconductor layer 231 via a contact 270. Thus, the third light shielding film 240 is a pixel potential. For example, the contact 270 is a contact plug that fills a hole that penetrates the insulating layers 222 and 223. The contact 270 also has a portion that covers the lightly doped drain region 231d in plan view. The third light shielding film 240 and the contact 270 are, for example, integral and formed by a damascene method.

The third light shielding film 244 is electrically coupled to the source region 231b of the second semiconductor layer 231 via a contact 271. For example, the contact 271 is a contact plug that fills a hole that penetrates the insulating layers 222 and 223. The third light shielding film 244 and the contact 271 are, for example, integral and formed by a damascene method.

A second contact 7 is disposed at the insulating layers 221 to 224. The second contact 7 is formed using, for example, a damascene method.

As shown in FIG. 7, the second contact 7 is disposed to surround the second gate electrode 232 in a direction along the Z-axis and a direction along the Y-axis. The second contact 7 is electrically coupled to the second gate electrode 232. In addition, a portion of the second contact 7 penetrates the insulating layer 221 and is electrically coupled to the fourth light shielding film 210. The fourth light shielding film 210 functions as a back gate.

Although not shown in the drawing in detail, the lightly doped drain region 231d is surrounded by the second contact 7, the third light shielding film 240 and the contact 270. For this reason, it is possible to curb the incidence of light on the lightly doped drain region 231d. Thus, it is possible to prevent the operation of the second transistor 23 from becoming unstable due to the incidence of light. As a result, it is possible to curb a concern that display defects such as uneven brightness occur. Thus, it is possible to curb deterioration in display quality.

As shown in FIG. 6, the scanning lines 241, the relay electrode 245, and the relay electrode 246 are disposed on the insulating layer 224. The scanning line 241 is electrically coupled to the second gate electrode 232 via the second contact 7 that penetrates the insulating layers 223 and 224. The relay electrode 245 is electrically coupled to the third light shielding film 240 via a contact 272 that penetrates the insulating layer 224. The relay electrode 246 is electrically coupled to the third light shielding film 244 via a contact 273 that penetrates the insulating layer 224.

The relay electrode 247 and the relay electrode 248 are disposed on the insulating layer 225. The relay electrode 247 is electrically coupled to the relay electrode 246 via a contact 275 that penetrates the insulating layer 225. The relay electrode 248 is electrically coupled to the relay electrode 245 via a contact 274 that penetrates the insulating layer 225.

The data line 242 is disposed on the insulating layer 226. The data line 242 is electrically coupled to the relay electrode 247 via a contact 276 that penetrates the insulating layer 226. Thus, the data line 242 is electrically coupled to the source region 231b via the contact 276, the relay electrode 247, the contact 275, the relay electrode 246, the contact 273, the third light shielding film 244 and the contact 271.

As shown in FIG. 7, the relay electrode 249 is disposed on the insulating layer 226. The relay electrode 249 is electrically coupled to the relay electrode 248 via a contact 277 that penetrates the insulating layer.

A capacitance element 24 is disposed on the insulating layer 227. The capacitance element 24 includes a pair of electrodes 2401 and 2402 and a dielectric layer 2403. The electrode 2401 is disposed on the insulating layer 227. The electrode 2402 is disposed on the insulating layer 228. The dielectric layer 2403 is disposed between the electrodes 2401 and 2402. The electrode 2401 also serves as the constant potential line 243 in FIG. 4. In addition, as shown in FIG. 7, the electrode 2402 is electrically coupled to the relay electrode 249 via a contact 278 that penetrates the insulating layers 227 and 228. Thus, as shown in FIG. 6 or 7, the electrode 2402 is electrically coupled to the drain region 231a via the contact 278, the relay electrode 249, the contact 277, the relay electrode 248, the contact 274, the relay electrode 245, the contact 272, the third light shielding film 240, and the contact 270.

As shown in FIG. 6, the pixel electrode 25 is disposed on the insulating layer 229. The pixel electrode 25 is electrically coupled to the electrode 2402 via a contact 279 that penetrates the insulating layer 229.

Each of the above-described scanning line 241, data line 242, electrode 2401, electrode 2402, third light shielding films 244 and 240, and relay electrodes 245, 246, 247, 248, and 249 contains, for example, a metal such as tungsten (W), titanium (Ti), chromium (Cr), iron, and aluminum (Al), a metal nitride, and a metal silicide. These may be single layers or multilayers. For example, these are constituted by a laminated body of an aluminum film and a titanium nitride film.

Furthermore, each of the above-described contacts 270 and 271 to 279 contains, for example, a metal such as tungsten (W), titanium (Ti), chromium (Cr), iron (Fe), and aluminum (Al), a metal nitride, and a metal silicide. Each of the contacts 270 and 271 to 279 may be a single layer or a multilayer. Each of the contacts 270 and 271 to 279 may be formed integrally with the electrode or wiring line to which it is coupled, or may be formed separately.

The arrangement of the wiring lines, the electrodes, and the like in the light shielding region A12 shown in FIGS. 6 and 7 is an example. For example, the light shielding region A12 may be provided with capacitive elements other than the capacitive element 24. The scanning line 241, the data line 242, and the capacitive element 24 are aligned in this order in the 21 direction, but may not be aligned in this order.

### 6. Configuration of Peripheral Region A20 of Element Substrate 2

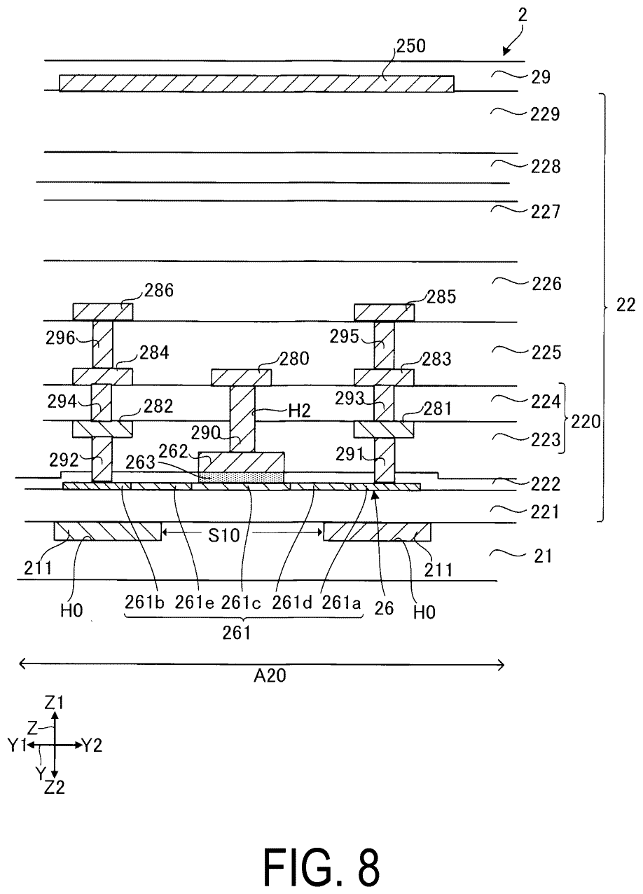

FIG. 8 shows a portion of the scanning line drive circuit 11 in the peripheral region A20 of FIG. 3. As shown in FIG. 8, a unit circuit 22a is provided at the laminated body 22. The unit circuit 22a is provided, for example, for each scanning line 241. The unit circuit 22a includes a transistor 26. The laminated body 22 is also provided with first light shielding films 281 and 282. The laminated body 22 is also provided with relay electrodes 283, 284, 285, and 286. A peripheral electrode 250 is also disposed on the laminated body 22. The peripheral electrode 250 is, for example, an electrode for ion trapping. The first substrate 21 is also provided with a plurality of second light shielding films 211.

The first substrate 21 has a plurality of concave portions H0. The second light shielding film 211 is disposed at each concave portion H0. The second light shielding film 211 is formed using, for example, a damascene method. The second light shielding film 211 is provided to prevent light from being incident on a semiconductor layer 261 of the transistor 26. The first substrate 21 may not have the concave portions H0. In this case, the second light shielding film 211 is disposed on a flat surface of the first substrate 21 which faces in the Z1 direction.

The transistor 26 is disposed on the insulating layer 221. The transistor 26 includes the semiconductor layer 261, a gate insulating film 263, and a gate electrode 262, which are disposed in a direction away from the first substrate 21. The semiconductor layer 261 is disposed on the insulating layer 221. The semiconductor layer 261 is disposed at the same layer as the second semiconductor layer 231 provided at the light shielding region A12. The gate electrode 262 is disposed on the insulating layer 222. The gate electrode 262 is disposed at the same layer as the second gate electrode 232 provided at the light shielding region A12. The gate insulating film 263 is interposed between the second gate electrode 232 and the second semiconductor layer 231. The gate insulating film 263 is disposed at the same layer as the second gate insulating film 233 provided at the light shielding region A12. The region of the insulating layer 222 which corresponds to the gate electrode 262 in plan view is equivalent to the gate insulating film 263. In addition, the insulating layers 223 and 224 are a first insulating layer 220 that covers the transistor 26.

The transistor 26 has, for example, an LDD structure. The semiconductor layer 261 includes a drain region 261a, a source region 261b, a channel region 261c, a lightly doped drain region 261d, and a lightly doped source region 261e. The channel region 261c is located between the drain region 261a and the source region 261b. The lightly doped drain region 261d is located between the channel region 261c and the drain region 261a. The lightly doped source region 261e is located between the channel region 261c and the source region 261b. The semiconductor layer 261 is formed of, for example, polysilicon. A region other than the channel region 261c is doped with impurities that increase conductivity. The impurity concentration in the lightly doped drain region 261d is lower than the impurity concentration in the drain region 261a. The impurity concentration in the lightly doped source region 261e is lower than the impurity concentration in the source region 261b. For example, the transistor 26 may not have an LDD structure, and for example, the lightly doped source region 261e may be omitted.

The gate electrode 262 is formed, for example, by doping polysilicon with impurities that increase conductivity. The gate electrode 262 may be formed using a material having conductivity such as a metal, a metal oxide, or a metal compound. The gate electrode 262 overlaps the channel region 261c of the semiconductor layer 261 in plan view. In addition, the gate insulating film 263 is constituted by a silicon oxide film formed, for example, by thermal oxidation or a CVD method.

Although not shown in the drawing in detail, the gate electrode 262 may be electrically coupled to the second light shielding film 211. That is, the second light shielding film 211 may be at the same potential as the gate electrode. Being at the same potential makes it even less likely that destruction of the gate insulating film 263 will occur. This is because when the second light shielding film 211 and the gate electrode 262 are at the same potential, electric field concentration due to a potential difference is less likely to occur. Furthermore, the back gate makes it easy to adjust the threshold voltage of the transistor 26.

Furthermore, the first light shielding films 281 and 282 are disposed on the insulating layer 223. The first light shielding films 281 and 282 are disposed at the same layer as the third light shielding films 240 and 244. The first light shielding film 281 is electrically coupled to the drain region 261a of the semiconductor layer 261 via a contact 291. The first light shielding film 282 is electrically coupled to the source region 261b of the semiconductor layer 261 via a contact 292.

The relay electrodes 280 and 283 and the relay electrode 284 are disposed on the insulating layer 224. The relay electrode 280 is electrically coupled to the gate electrode 262 via a first contact 290 that fills a contact hole H2 which is a hole that penetrates the insulating layers 223 and 224. The relay electrode 283 is electrically coupled to the first light shielding film 281 via a contact 293 that penetrates the insulating layer 224. The relay electrode 284 is electrically coupled to the first light shielding film 282 via a contact 294 that penetrates the insulating layer 224.

The relay electrode 285 and the relay electrode 286 are disposed on the insulating layer 225. The relay electrode 285 is electrically coupled to the relay electrode 283 via a contact 295 that penetrates the insulating layer 225. The relay electrode 286 is electrically coupled to the relay electrode 284 via a contact 296 that penetrates the insulating layer 225. Each of the relay electrode 285 and the relay electrode 286 is electrically coupled to elements such as other transistors adjacent to the transistor 26.

Various wiring lines, electrodes or light shielding layers (not shown) may be disposed on the insulating layer 226. Furthermore, a peripheral electrode 250 is disposed on the insulating layer 229. The peripheral electrode 250 is disposed at the same layer as the pixel electrode 25.

From the viewpoint of ease of manufacture, it is preferable that the various wiring lines or electrodes disposed at the light shielding region A12 and the various wiring lines or electrodes disposed at the peripheral region A20 be formed of the same material in each layer.

### 7. Unit Circuit 22a

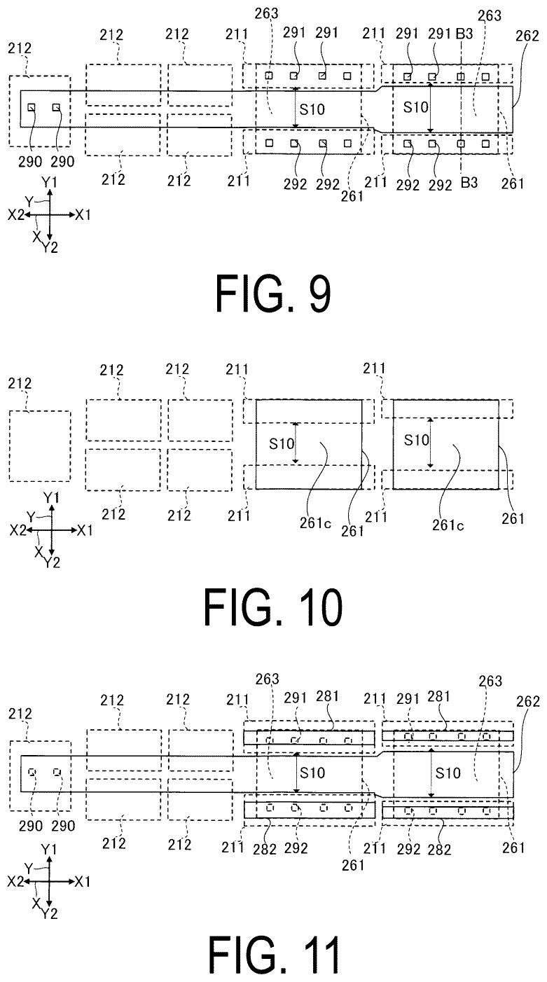

FIG. 9 is a diagram showing a planar arrangement of the transistor 26 in the unit circuit 22a of FIG. 8. A cross-section taken along line B3-B3 in FIG. 9 is equivalent to the diagram of FIG. 8. Furthermore, FIG. 10 is a diagram showing a planar arrangement of the second light shielding film 211 and the semiconductor layer 261 in FIG. 8. FIG. 11 is a diagram showing a planar arrangement of the first light shielding films 281 and 282 and the second light shielding film 211 in FIG. 8.

As shown in FIG. 9, the unit circuit 22a includes two transistors 26. The unit circuit 22a includes, for example, a NOT circuit. One of the two transistors 26 is an n-channel MOS transistor, and the other is a p-channel MOS transistor. In this embodiment, the two transistors 26 share the gate electrode 262 in common.

In this embodiment, four second light shielding films 211 are provided as the plurality of second light shielding films 211. In this embodiment, in addition to the plurality of second light shielding films 211, a plurality of light shielding films 212 are provided. The plurality of light shielding films 212 are disposed to be spaced apart from each other. In FIG. 9, the plurality of light shielding films 212 are located on the left of the plurality of second light shielding films 211.

Slits are provided between the plurality of second light shielding films 211. Specifically, a gap S10 is provided between two second light shielding films 211 provided on both sides of the semiconductor layer 261 along the Y-axis. The gap S10 overlaps the gate electrode 262 in plan view.

As shown in FIG. 10, the semiconductor layer 261 overlaps two second light shielding films 211 that are spaced apart from each other along the Y-axis. However, a portion of the semiconductor layer 261 does not overlap the second light shielding film 211 in plan view. Specifically, the channel region 261c of the semiconductor layer 261 does not overlap the second light shielding film 211 in plan view. In addition, the plurality of light shielding films 212 do not overlap the semiconductor layer 261.

In addition, as shown in FIG. 9, the gate electrode 262 extends in a direction along the X-axis. The gate electrode 262 is disposed at a different position from the second light shielding film 211 in plan view. That is, the gate electrode 262 does not overlap the second light shielding film 211 in plan view. Thus, the gate insulating film 263 does not overlap the second light shielding film 211 in plan view. Furthermore, the first contact 290 does not overlap the second light shielding film 211 in plan view.

In addition, as shown in FIG. 11, the first light shielding film 281 overlaps the second light shielding film 211 in plan view.

### 8. First Light Shielding Film and Second Light Shielding Film

As described above, the first light shielding films 281 and 282 shown in FIG. 8 are provided on the first insulating layer 220. In addition, the second light shielding film 211 is provided between the first substrate 21 and the semiconductor layer 261. The second light shielding film 211 overlaps the semiconductor layer 261 when viewed in the normal direction of the first substrate 21, and is provided at a different position from the gate electrode 262. That is, the second light shielding film 211 overlaps the semiconductor layer 261 in plan view, but does not overlap the gate electrode 262 in plan view. In addition, the gate insulating film 263 overlaps the gate electrode 262 in plan view. For this reason, the second light shielding film 211 does not overlap the gate insulating film 263 in plan view. In this embodiment, the second light shielding film 211 is provided on both sides of the gate electrode 262 in the Y-axis while avoiding the gate electrode 262 in plan view.

Since the second light shielding film 211 does not overlap the gate electrode 262 in plan view, it is possible to prevent the gate insulating film 263 from being destroyed due to etching at the time of forming the contact hole H2 which is a through hole for disposing the first contact 290. For this reason, it is possible to curb a concern that an operational failure will occur in the transistor 26 due to the destruction of the gate insulating film 263. Thus, it is possible to curb deterioration in display quality.

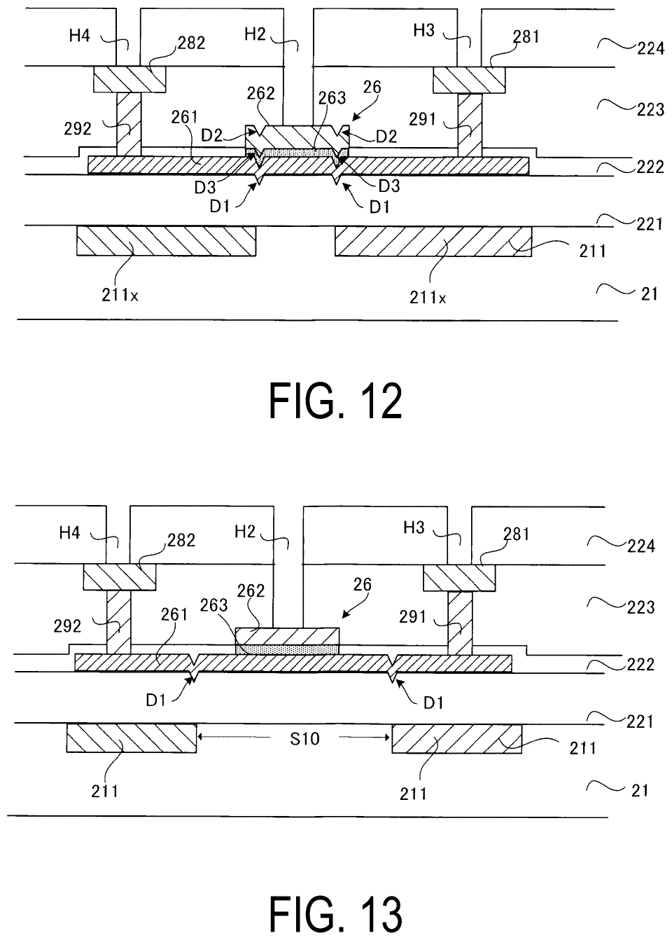

FIG. 12 is a diagram for describing etching of the contact hole H2 in a comparative example. In the comparative example of FIG. 12, a second light shielding film 211x overlaps the semiconductor layer 261 in plan view. In this case, when the contact hole H2 is formed, there is a concern that etching may cause damage D2 to the gate electrode 262, damage D3 to the gate insulating film 263, and damage D1 to the semiconductor layer 261. This is considered to be because an electric field generated by the charge of etching is concentrated on the second light shielding film 211x. In particular, it is considered that an electric field is concentrated at the end of the second light shielding film 211x. For this reason, there is a concern that the gate insulating film 263 overlapping the end of the second light shielding film 211x in plan view may be destroyed. When the damage D3 occurs in the gate insulating film 263, there is a concern that a leak current may flow, causing an operational failure in the transistor 26.

FIG. 13 is a diagram for describing etching of contact hole H2 in this embodiment. In the transistor 26 of this embodiment in FIG. 13, the second light shielding film 211 overlaps the semiconductor layer 261 in plan view, but does not overlap the gate electrode 262 and the gate insulating film 263 in plan view. In this case, when the contact hole H2 is formed, damage D1 occurs to the semiconductor layer 261 due to the etching, but damage is unlikely to occur to the gate electrode 262 and the gate insulating film 263. For this reason, according to this embodiment, it is possible to reduce a concern that the gate insulating film 263 is destroyed. Thus, it is possible to avoid the occurrence of an operational failure in the transistor 26 due to the destruction.

In this embodiment, similarly to the second light shielding film 211, the first light shielding films 281 and 282 do not overlap the gate electrode 262 in plan view. For this reason, the first light shielding films 281 and 282 do not overlap the gate insulating film 263 in plan view. In other words, the first light shielding films 281 and 283 are provided at different positions from the gate insulating film 263 in plan view.

Furthermore, the first contact 290 shown in FIGS. 8 and 9 is provided at a different position from the second light shielding film 211 when viewed in the normal direction of the first substrate 21. That is, the first contact 290 does not overlap the second light shielding film 211 in plan view. For this reason, the contact hole H2 does not overlap the second light shielding film 211 in plan view. Thus, it is possible to prevent an electric field generated by the charge of etching from being concentrated on the second light shielding film 211, compared to a case where the contact hole H2 overlaps the second light shielding film 211 in plan view.

Furthermore, in this embodiment, the first contact 290 is a contact plug filled in the contact hole H2 which is a hole formed in the first insulating layer 220. The contact plug makes it easier to increase an aspect ratio compared to a trench electrode. For this reason, the aspect ratio of the contact hole H2 tends to become high. Thus, an etching time for forming the contact hole H2 tends to increase. Then, the electric field generated by the charge of etching is likely to be concentrated on the second light shielding film 211. For this reason, when the first contact 290 is a contact plug, it is particularly preferable that the second light shielding film 211 do not overlap the gate electrode 262 and the gate insulating film 263 in plan view.

Here, in order to avoid damage to the gate insulating film 263 due to the concentration of the electric field generated by the charge of etching on the second light shielding film 211, it is preferable not to provide the second light shielding film 211. However, when the second light shielding film 211 is not provided, there is a concern that return light of light LL will be incident on the semiconductor layer 261. In particular, when light is incident on the lightly doped drain region 263d, there is a concern that the operation of the transistor 26 may become unstable.

In this embodiment, the second light shielding film 211 overlaps the lightly doped drain region 263d in plan view. For this reason, it is possible to curb a concern that the return light of the light LL may be incident on the lightly doped drain region 263d, compared to a case where the second light shielding film 211 does not overlap the lightly doped drain region 263d in plan view. Thus, the operation of the transistor 26 is prevented from becoming unstable due to the incidence of the light. In particular, it is preferable to curb the incidence of return light in an electronic apparatus such as a projector.

Furthermore, the transistor 26 is provided at the scanning line drive circuit 11 which serves as the peripheral circuit 10. In the transistor 26 provided at the scanning line drive circuit 11, the second light shielding film 211 is disposed not to overlap the gate electrode 262 and the gate insulating film 263 in plan view. By disposing the second light shielding film 211 in this manner for the transistor 26 provided at the scanning line drive circuit 11, a display failure in the electro-optical device 100 can be particularly effectively curbed.

The “second light shielding film” exemplified by the second light shielding film 211 may be provided at a part other than the transistor 26. For example, the “second light shielding film” may be provided at one or more of the transistors other than the transistor 26 in the scanning line drive circuit 11, the transistors in the sampling circuit 15, and the transistors in the inspection circuit 14. By providing the “second light shielding film” in the peripheral circuit 10, a display failure of the electro-optical device 100 can be effectively curbed.

### 8. Fourth Light Shielding Film 210

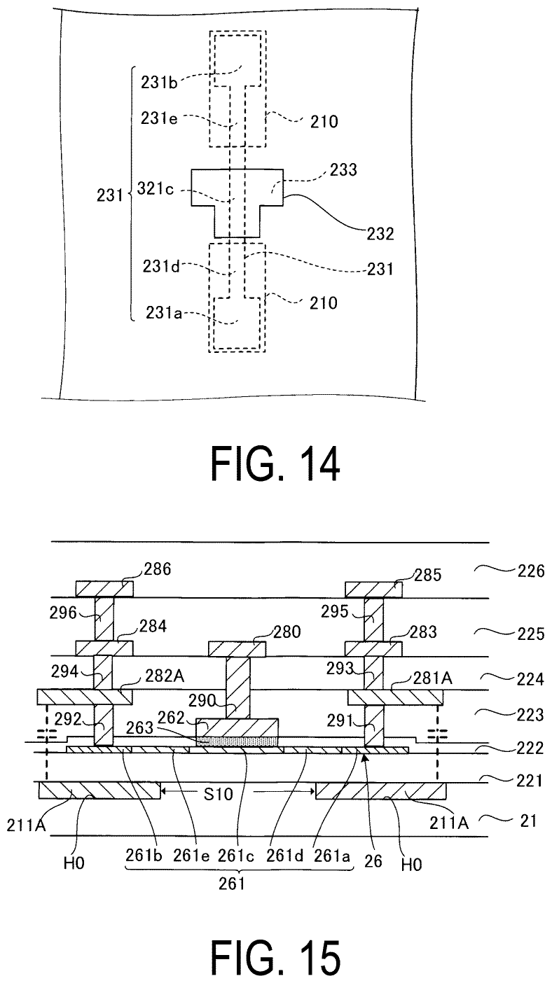

FIG. 14 is a diagram showing a planar arrangement of the fourth light shielding film 210 and the second transistor 23 shown in FIG. 6. As shown in FIG. 14, each fourth light shielding film 210 overlaps the second semiconductor layer 231 of the second transistor 23 in plan view. One fourth light shielding film 210 overlaps the drain region 231a and the lightly doped drain region 231d in plan view. The other fourth light shielding film 210 overlaps the source region 231b and the lightly doped source region 231e in plan view. The fourth light shielding film 210 overlaps the lightly doped drain region 231d in plan view, and thus it is possible to curb a display failure due to the incidence of light on the lightly doped drain region 231d.

Furthermore, the fourth light shielding film 210 is provided not to overlap the second gate electrode 232 and the second gate insulating film 233 in plan view. That is, a gap is provided between the fourth light shielding films 210. The fourth light shielding film 210 does not overlap the second gate insulating film 233 in plan view, and thus it is possible to curb damage to the second gate insulating film 233 in the second transistor 23. It may be considered that each of the third light shielding films 240 and 244 is equivalent to a “first light shielding film”, and the fourth light shielding film 210 is equivalent to a “second light shielding film”.

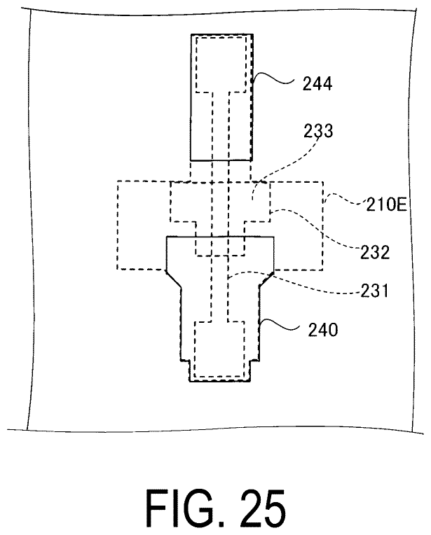

FIG. 25 is a diagram showing a planar arrangement of a fourth light shielding film 210E and the second transistor 23 in a modification example. It is desirable to avoid a display failure caused by light LL and return light being incident on the second semiconductor layer 231 disposed at the display region A10. For this reason, as shown in FIG. 25, the fourth light shielding film 210E disposed at the display region A10 may overlap the second semiconductor layer 231 in plan view, and may overlap the second semiconductor layer 231 to cover it.

### 2.Second Embodiment

In a second embodiment described below, for elements having the same functions as those in the first embodiment, the reference numerals used in the description of the first embodiment will be used, and detailed descriptions thereof will be omitted as appropriate.

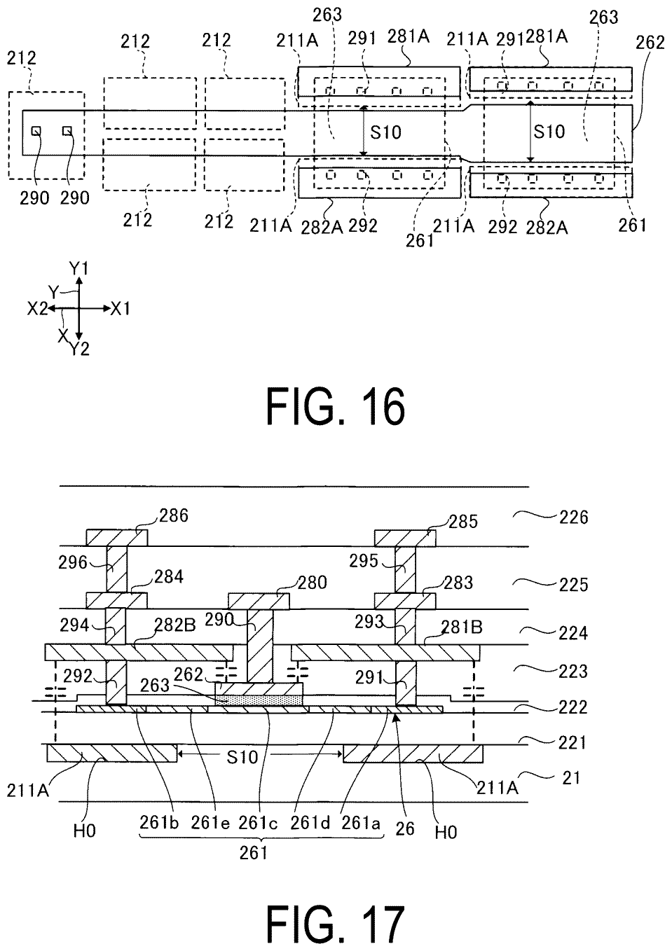

FIG. 15 is a cross-sectional view showing first light shielding films 281A and 282A and a second light shielding film 211A in the second embodiment. FIG. 16 is a plan view showing the first light shielding films 281A and 282A and the second light shielding film 211A in the second embodiment.

Each of the first light shielding films 281A and 282A shown in FIGS. 15 and 16 has a portion that overlaps the semiconductor layer 261 in plan view and a portion that does not overlap the semiconductor layer 261 in plan view. Similarly, each of the plurality of second light shielding films 211A has a portion that overlaps the semiconductor layer 261 in plan view and a portion that does not overlap the semiconductor layer 261 in plan view.

In addition, the second light shielding film 211A has a portion that overlaps the first light shielding film 281A or 282A at a different position from the semiconductor layer 261 in plan view. That is, the second light shielding film 211A has a portion that does not overlap the semiconductor layer 261 in plan view, but overlaps the first light shielding film 281A or 282A in plan view. For this reason, the first light shielding film 281A or 282A and the second light shielding film 211A can be capacitively coupled. That is, coupling between the first light shielding film 281A and the second light shielding film 211A can function as a capacitive coupling. Thus, an electric field generated by the charge of etching of the contact hole H2 described above can be absorbed by the capacitive coupling. Thus, it is possible to alleviate the concentration of the electric field at the end of the second light shielding film 211A. Thus, it is possible to more reduce a concern that the gate insulating film 263, the gate electrode 262, and the semiconductor layer 261 may be destroyed due to the concentration of the electric field than in the first embodiment. Thus, it is possible to more effectively avoid the occurrence of an operational failure of the transistor 26 caused by the destruction than in the first embodiment.

### 3. Third Embodiment

In a third embodiment described below, for elements having the same functions as those inf the second embodiment, the reference numerals used in the description of the second embodiment will be used, and detailed descriptions thereof will be omitted as appropriate.

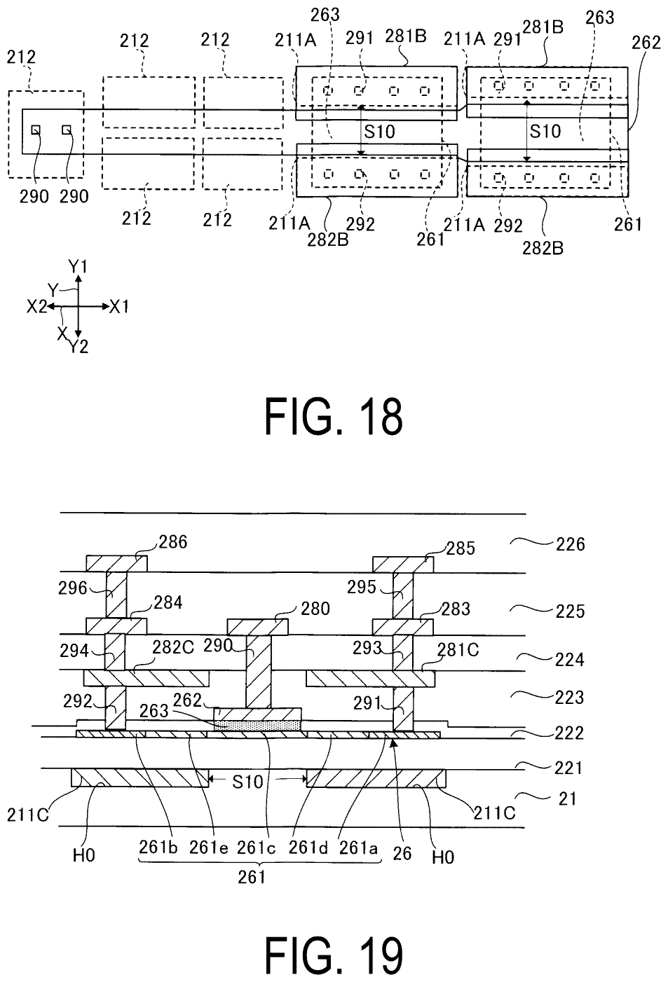

FIG. 17 is a cross-sectional view showing first light shielding films 281B and 282B and a second light shielding film 211A in the third embodiment. FIG. 18 is a plan view showing the first light shielding films 281B and 282B and the second light shielding film 211A in the third embodiment.

As shown in FIGS. 17 and 18, the first light shielding film 281B further has a portion that overlaps a gate electrode 262 in plan view. For this reason, the first light shielding film 281B and the gate electrode 262 can be capacitively coupled. That is, coupling between the first light shielding film 281B and the gate electrode 262 can function as a capacitive coupling. Thus, an electric field generated by the charge of etching of the contact hole H2 described above can be absorbed by the capacitive coupling. Thus, it is possible to alleviate the concentration of the electric field at the end of the second light shielding film 211A. Thus, it is possible to more reduce a concern that the gate insulating film 263, the gate electrode 262, and the semiconductor layer 261 may be destroyed due to the concentration of the electric field than in the second embodiment. Thus, it is possible to more effectively avoid the occurrence of an operational failure of the transistor 26 caused by the destruction than in the second embodiment.

Similarly, the first light shielding film 282B has a portion that overlaps the gate electrode 262 in plan view. For this reason, the first light shielding film 282B and the gate electrode 262 can be capacitively coupled. That is, coupling between the first light shielding film 282B and the gate electrode 262 can function as a capacitive coupling. Thus, an electric field generated by the charge of etching can be absorbed by the capacitive coupling. Thus, it is possible to reduce a concern that the gate insulating film 263, the gate electrode 262 and the semiconductor layer 261 may be destroyed due to the concentration of the electric field and to more effectively avoid the occurrence of an operational failure of the transistor 26 than in the second embodiment.

Furthermore, the first light shielding film 281B is provided to cover a lightly doped drain region 261d in plan view. Furthermore, the first light shielding film 282B is provided to cover a lightly doped source region 261e in plan view. The first light shielding film 282B is provided to cover the lightly doped drain region 261d in plan view, and thus it is possible to curb the incidence of light on the lightly doped drain region 261d. Thus, the operation of the transistor 26 is prevented from becoming unstable due to the incidence of light LL.

### B. Modification Example

The embodiments illustrated above may be modified in various ways. Specific modifications that can be applied to the above-described embodiments are illustrated below. Two or more aspects arbitrarily selected from examples below may be combined appropriately as long as contradiction is not caused.

### B1. First Modification Example

FIG. 19 is a cross-sectional view showing first light shielding films 281C and 282C in a first modification example. As shown in FIG. 19, the first light shielding film 281C is provided to overlap the lightly doped drain region 261d in plan view and cover the lightly doped drain region 261d in plan view. Similarly, the first light shielding film 282C is provided to overlap the lightly doped source region 261e in plan view and cover the lightly doped source region 261e in plan view. The first light shielding film 281C overlaps the lightly doped drain region 261d in plan view, and thus it is possible to prevent the operation of the transistor 26 from becoming unstable due to the incidence of light LL on the lightly doped drain region 261d.

Further, a second light shielding film 211C is provided to overlap the lightly doped drain region 261d in plan view and cover the lightly doped drain region 261d in plan view. Further, the second light shielding film 211C is provided to overlap the lightly doped source region 261e in plan view and cover the lightly doped source region 261e in plan view. The second light shielding film 211C overlaps the lightly doped drain region 261d in plan view, and thus the operation of the transistor 26 is prevented from becoming unstable due to the incidence of the light LL on the lightly doped drain region 261d.

### B2. Second Modification Example

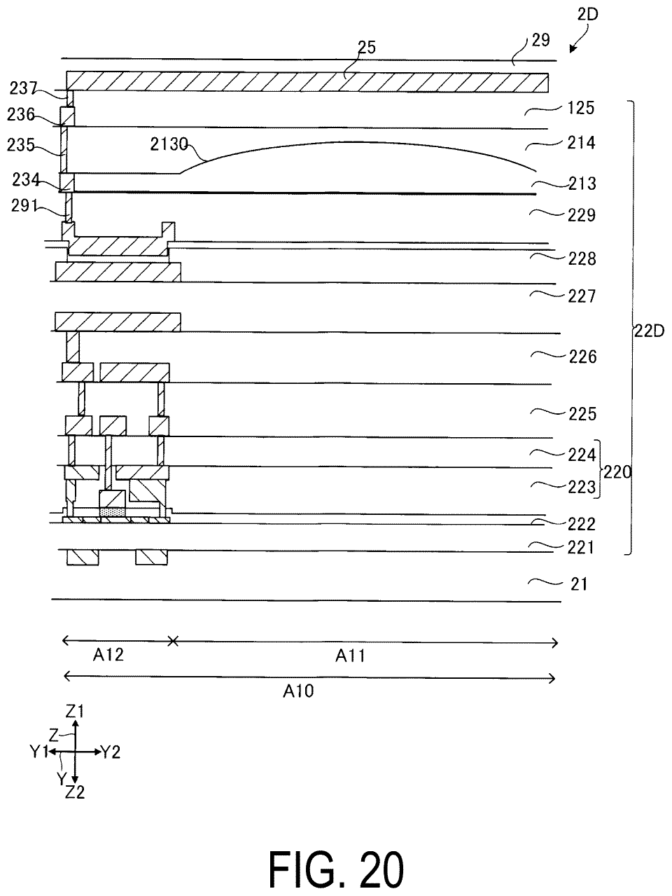

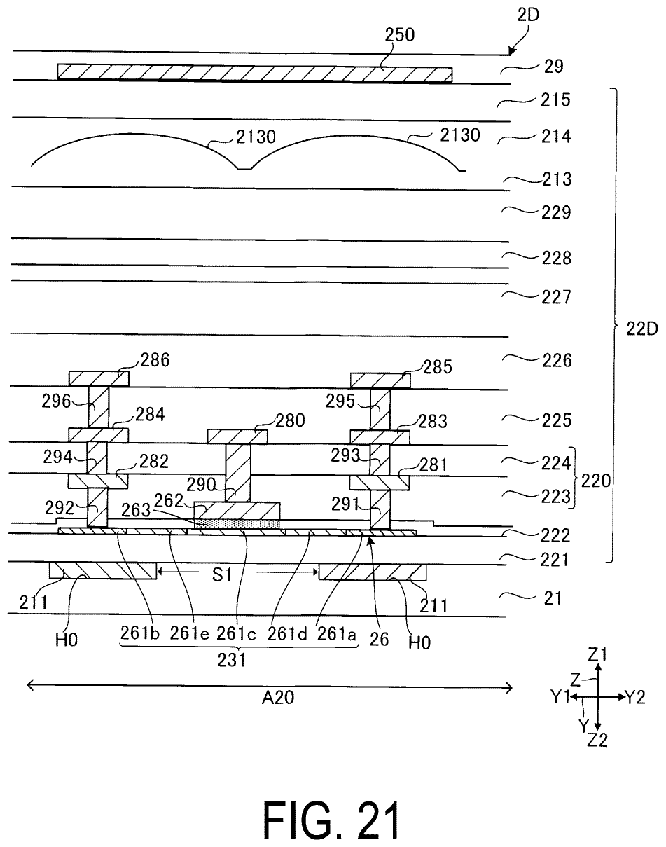

FIG. 20 is a diagram showing a portion of a display region A10 of an element substrate 2D in a second modification example. FIG. 21 is a diagram showing a portion of a peripheral region A20 of the element substrate 2D in the second modification example. A laminated body 22D of the element substrate 2D shown in FIGS. 20 and 21 further includes a lens layer 213 and insulating layers 214 and 215. The lens layer 213 and the insulating layers 214 and 215 are laminated in this order from an insulating layer 229. The materials of the lens layer 213, and the insulating layers 214 and 215 are inorganic materials containing silicon such as silicon oxide and silicon oxynitride.

As shown in FIG. 20, in a light shielding region A12 of the display region A10, a relay electrode 234 is disposed on the insulating layer 229. The relay electrode 234 is coupled to a contact 291. A relay electrode 236 is disposed on the insulating layer 214. The relay electrode 236 is coupled to the relay electrode 234 via a contact 235 that penetrates the lens layer 213 and the insulating layer 214. In the light shielding region A12, a pixel electrode 25 is disposed on the insulating layer 215. The pixel electrode 25 is coupled to the relay electrode 236 via a contact 237 that penetrates the insulating layer 215. Furthermore, as shown in FIG. 21, in the peripheral region A20, a peripheral electrode 250 is disposed on the insulating layer 215.

Each of the relay electrodes 234 and 236 contains, for example, a metal such as aluminum, a metal nitride, a metal silicide, and the like. Furthermore, each of the contacts 235 and 237 described above contains, for example, a metal such as tungsten and aluminum, a metal nitride, a metal silicide, and the like.

The lens layer 213 also has a plurality of lens surfaces 2130. In the display region A10, one lens surface 2130 is provided for one pixel electrode 25. Thus, in the display region A10, one lens surface 2130 is provided for one second transistor 23. On the other hand, as shown in FIG. 21, in the peripheral region A20, any number of lens surfaces 2130 may be provided for one transistor 26. In the example shown in the drawing, two lens surfaces 2130 are provided for one transistor 26.

As described above, in the second modification example, a second light shielding film 211 does not overlap a gate electrode 262 in plan view, and thus it is possible to curb the destruction of a gate insulating film 263.

In each of the embodiments described above, the electro-optical device 100 using an active matrix scheme is illustrated, but the present embodiment is not limited thereto and a drive scheme for the electro-optical device 100 may be, for example, a passive matrix scheme.

The driving scheme of the “electro-optical device” is not limited to a vertical electric field scheme, but may be a transverse electric field scheme. An example of the transverse electric field scheme may include an In Plane Switching (IPS) mode. Further, examples of the vertical electric field scheme may include a Twisted Nematic (TN) mode, a Vertical Alignment (VA) mode, a PVA mode, and an Optically Compensated Bend (OCB) mode.

### 2. Electronic Apparatus

The electro-optical device 100 can be used in various electronic apparatuses.

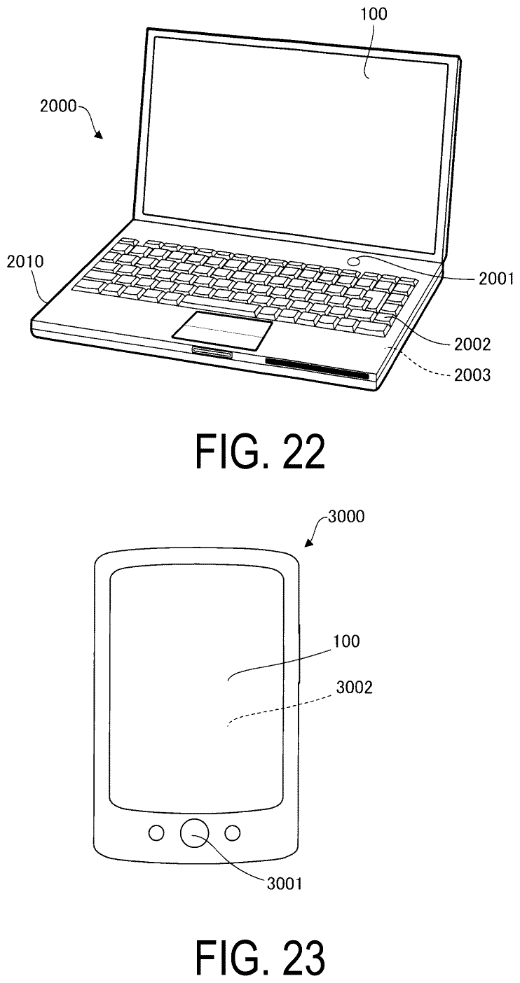

FIG. 22 is a perspective view showing a personal computer 2000 that is an example of the electronic apparatus. The personal computer 2000 includes the electro-optical device 100 that displays various images, a body unit 2010 in which a power switch 2001 and a keyboard 2002 are installed, and a control unit 2003. The control unit 2003 includes, for example, a processor and a memory, and controls an operation of the electro-optical device 100.

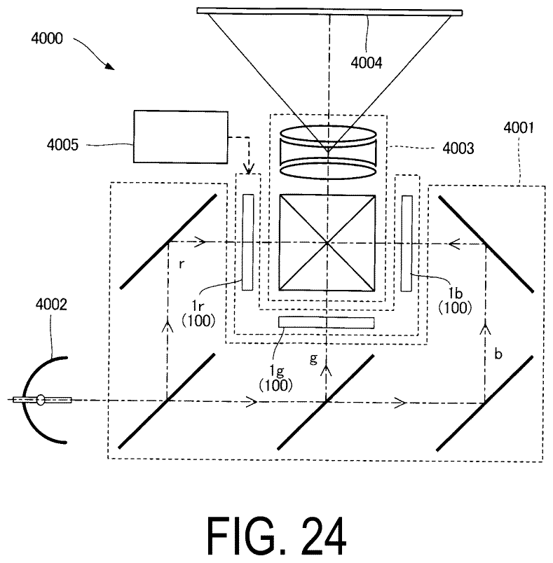

FIG. 23 is a plan view showing a smartphone 3000 that is an example of the electronic apparatus. The smartphone 3000 includes an operation button 3001, an electro-optical device 100 that displays various images, and a control unit 3002. Screen content displayed on the electro-optical device 100 is changed according to an operation of the operation button 3001. The control unit 3002 includes, for example, a processor and a memory, and controls an operation of the electro-optical device 100.

FIG. 24 is a schematic diagram showing a projector that is an example of the electronic apparatus. A projection type display apparatus 4000 is, for example, a three-panel projector. An electro-optical device 1r is an electro-optical device 100 corresponding to a red display color, an electro-optical device 1g is an electro-optical device 100 corresponding to a green display color, and an electro-optical device 1b is an electro-optical device 100 corresponding to a blue display color. That is, the projection type display apparatus 4000 includes three electro-optical devices 1r, 1g, and 1b corresponding to respective red, green, and blue display colors. A control unit 4005 includes, for example, a processor and a memory, and controls an operation of the electro-optical device 100.

An illumination optical system 4001 supplies a red component r of the light emitted from an illumination apparatus 4002, which is a light source, to the electro-optical device 1r, a green component g to the electro-optical device 1g, and a blue component b to the electro-optical device 1b. Each of the electro-optical devices 1r, 1g, and 1b functions as an optical modulator such as a light valve that modulates each monochromatic light beam supplied from the illumination optical system 4001 according to a displayed image. A projection optical system 4003 combines the light emitted from the respective electro-optical devices 1r, 1g, and 1b and projects the combined light onto a projection surface 4004.

The electronic apparatus includes the electro-optical device 100 described above and a control unit 2003, 3002, or 4005. In the electro-optical device 100 described above, damage to the gate insulating film 263 is curbed, and an operational failure of the transistor 26 is unlikely to occur. In this manner, the concern of the occurrence of display failures is curbed. Thus, with the electro-optical device 100, the display quality of the personal computer 2000, the smartphone 3000, or the projection-type display device 4000 can be increased.

An electronic apparatus to which the electro-optical device of the present disclosure is applied is not limited to the illustrated device, and examples thereof may include a personal digital assistant (PDA), a digital still camera, a television, a video camera, a car navigation apparatus, an in-vehicle display, an electronic notebook, an electronic paper, a calculator, a word processor, a workstation, a videophone, and a point of sale (POS) terminal. Further, examples of the electronic apparatus to which the present disclosure is applied may include a printer, a scanner, a copier, a video player, and a device including a touch panel.

Although the present disclosure has been described above based on the preferred embodiments, the present disclosure is not limited to the above-described embodiments. Further, a configuration of the respective portions of the present disclosure can be replaced with any configuration that performs the same function as that in the embodiment described above, or any configuration can be added.

Further, in the above description, the liquid crystal display device has been described as an example of the electro-optical device of the present disclosure, but the electro-optical device of the present disclosure is not limited thereto. For example, the electro-optical device of the present disclosure can be applied to an image sensor, or the like.

What is claimed is:

1. An electro-optical device, comprising:
a substrate;
a transistor including a semiconductor layer, a gate insulating film, and a gate electrode that are aligned in a direction away from the substrate;
a first insulating layer covering the transistor;
a first contact provided at the first insulating layer and coupled to the gate electrode;
a first light shielding film provided at the first insulating layer; and
a second light shielding film provided between the substrate and the semiconductor layer,
wherein the second light shielding film overlaps the semiconductor layer when viewed in a normal direction of the substrate, and is provided at a different position from the gate electrode.

2. The electro-optical device according to claim 1, wherein the second light shielding film is provided at a different position from the gate insulating film when viewed in the normal direction.

3. The electro-optical device according to claim 1, wherein the second light shielding film is provided on both sides of the gate electrode while avoiding the gate electrode when viewed in the normal direction.

4. The electro-optical device according to claim 1, wherein the first contact is provided at a different position from the second light shielding film when viewed in the normal direction.

5. The electro-optical device according to claim 1, comprising a display region for displaying an image, and a peripheral region provided outside the display region,
wherein the peripheral region includes a peripheral circuit electrically coupled to wiring lines disposed at the display region, and
the peripheral circuit includes the transistor, the first contact, the first light shielding film, and the second light shielding film.

6. The electro-optical device according to claim 1, comprising a display region for displaying an image, and a peripheral region provided outside the display region,
wherein a scanning line drive circuit electrically coupled to a scanning line is provided at the peripheral region, and
the scanning line drive circuit includes the transistor, the first contact, the first light shielding film, and the second light shielding film.

7. The electro-optical device according to claim 5, wherein
the display region is provided with a second transistor, the first insulating layer, a second contact, a third light shielding film, and a fourth light shielding film,
the second transistor includes a second semiconductor layer, a second gate insulating film, and a second gate electrode that are aligned in a direction away from the substrate,
the second transistor is disposed at a same layer as the transistor,
the third light shielding film is disposed at a same layer as the first light shielding film,
the fourth light shielding film is disposed at a same layer as the second light shielding film, and
the second contact is provided at the first insulating layer and coupled to the second gate electrode, and the fourth light shielding film is disposed so as to cover the semiconductor layer when viewed in the normal direction.

8. The electro-optical device according to claim 1, wherein the first contact is a contact plug filled into a hole formed at the first insulating layer.

9. The electro-optical device according to claim 1, wherein the second light shielding film is at a same potential as the gate electrode.

10. The electro-optical device according to claim 1, wherein
the semiconductor layer includes a channel region, a drain region, and a lightly doped drain region having a lower impurity concentration than the drain region, and
the second light shielding film is provided so as to cover the lightly doped drain region when viewed in the normal direction.

11. The electro-optical device according to claim 10, wherein the first light shielding film is provided so as to cover the lightly doped drain region when viewed in the normal direction.

12. The electro-optical device according to claim 1, wherein the first light shielding film includes a portion overlapping the second light shielding film when viewed in the normal direction.

13. The electro-optical device according to claim 1, wherein the first light shielding film includes a portion overlapping the gate electrode when viewed in the normal direction.

14. An electronic apparatus comprising:
the electro-optical device according to claim 1; and
a control unit configured to control an operation of the electro-optical device.
